(19) United States
(12) Patent Application Publication
(10) Pub. No.: US 2022/0367615 A1
(43) Pub. Date: Nov. 17, 2022

(54) SUPERJUNCTION SEMICONDUCTOR DEVICE AND METHOD FOR MANUFACTURING SAME

(71) Applicant: DB HiTek Co., Ltd., Bucheon-si (KR)

(72) Inventors: Min Gi JO, SeouI (KR); Myeong Bum PYUN, lncheon (KR)

(21) Appl. No.: 17/731,623

(22) Filed: Apr. 28, 2022

(30) Foreign Application Priority Data
May 17, 2021 (KR) 10-2021-0063226

(51) Int. Cl. H01L 29/06; H01L 29/10; H01L 29/40; H01L 29/78; H01L 21/225; H01L 21/265; H01L 21/761; H01L 21/765; H01L 29/66

(52) U.S. Cl. CPC H01L 29/0634; H01L 29/1095; H01L 29/402; H01L 29/7811; H01L 21/2253; H01L 21/26513; H01L 21/761; H01L 21/765; H01L 29/66712

(57) ABSTRACT

Disclosed is a superjunction semiconductor device and a method for manufacturing the same and, more particularly, to a superjunction semiconductor device and a method for manufacturing the same seeking to improve on-resistance characteristics of the device without degrading breakdown voltage characteristics by forming a second conductivity type impurity region on and/or in a surface of a substrate in a cell region C to increase a second conductivity type impurity concentration in the device.

### CROSS REFERENCE TO RELATED APPLICATION(S)

The present application claims priority to Korean Patent Application No. 10-2021-0063226, filed on May 17, 2021, the entire contents of which are incorporated herein by reference.

### TECHNICAL FIELD

The present disclosure relates to a superjunction semiconductor device and a method for manufacturing the same and, more particularly, to a superjunction semiconductor device and a method for manufacturing the same seeking to improve on-resistance characteristics of the semiconductor device without degrading breakdown voltage characteristics by forming a second conductivity type impurity region on or in a substrate in a cell region C to increase a second conductivity type impurity concentration in the semiconductor device.

### BACKGROUND ART

For high voltage power MOSFETs, the specific resistance and thickness of a drift region may be increased in order to increase a breakdown voltage to improve high voltage characteristics. Since the breakdown voltage is proportional to an on-resistance of the power MOSFET, there is a problem that the on-resistance increases as the breakdown voltage increases.

To solve this, a superjunction power MOSFET having alternating p-type regions and n-type regions in an active region has been introduced. Alternating p-type and n-type regions are ideal for charge balancing, so that they deplete each other under reverse voltage conditions, thereby making them more resistant to breakdown. Accordingly, the use of stripe P pillar type superjunction power MOSFETs with high voltage characteristics and low on-resistance characteristics compared to existing planar power MOSFETs is increasing.

FIG. 1 is a schematic cross-sectional view of a conventional superjunction semiconductor device.

Referring to FIG. 1, in the conventional superjunction semiconductor device 9, a second conductivity type epitaxial layer 910 is formed on a first conductivity type substrate 901. A plurality of first conductivity type pillar regions 930 may be formed in the epitaxial layer 910 spaced apart from each other in a lateral direction. In such a device 9, it is difficult to improve device characteristics by implementing a high breakdown voltage value together with a low on-resistance value because the on-resistance value and the breakdown voltage value have a trade-off relationship. That is, when the surface resistance value is decreased to reduce the on-resistance value, during the ON operation of the device, the breakdown voltage value decreases, as a strong electric field is formed in or near the surface area. Conversely, when the doping concentration in or adjacent to a p-n junction is optimized to improve the ON-state breakdown voltage, the on-resistance value increases.

To solve such problems, the present disclosure concerns a novel superjunction semiconductor device with an improved structure and a method for manufacturing the same.

### DOCUMENT OF RELATED ART

Korean Patent Application Publication No. 10-2005-0052597, “SUPERJUNCTION SEMICONDUCTOR DEVICE”

### SUMMARY OF THE INVENTION

The present disclosure has been made to solve the problems of the related art, and an objective of the present disclosure is to provide a superjunction semiconductor device and a method for manufacturing the same, which improve on-resistance characteristics of the semiconductor device while maintaining the ON-state breakdown voltage characteristics by forming a second conductivity type impurity region between a substrate and an epitaxial layer to increase an n-type impurity concentration, which results in a carrier increase.

Moreover, an objective of the present disclosure is to provide a superjunction semiconductor device and a method for manufacturing the same, which promote the convenience of manufacturing the semiconductor device and prevent degradation of the breakdown voltage characteristics by additionally performing only an ion implantation process on the substrate, without changing the thickness of the epitaxial layer and/or the pillar doping concentration.

Furthermore, an objective of the present disclosure is to provide a superjunction semiconductor device and a method for manufacturing the same, which further improve the on-resistance characteristics resulting from a relatively thick impurity region in the substrate formed by a thermal diffusion process after the formation of a first undoped epitaxial layer.

### Technical Solution

The present disclosure may be implemented by embodiments having one or more of the following configurations in order to achieve one or more of the above-described objectives.

According to one or more embodiments of the present disclosure, a superjunction semiconductor device of the present disclosure includes a substrate; a second conductivity type epitaxial layer on the substrate; a plurality of first conductivity type pillars laterally spaced apart from each other in the epitaxial layer; a first conductivity type body region connected to one of the pillars in a cell region (e.g., of the semiconductor device); a second conductivity type source in the body region; a gate oxide film on the epitaxial layer; a gate electrode on the gate oxide film; a drain electrode on the substrate; and a second conductivity type impurity region on or in (e.g., at a surface of) the substrate.

According to one or more other embodiments of the present disclosure, in the superjunction semiconductor device, the impurity region may be or comprise a lightly doped region.

According to yet one or more other embodiments of the present disclosure, in the superjunction semiconductor device, the impurity region may be in the cell region.

According to yet one or more other embodiments of the present disclosure, the superjunction semiconductor device may further include a first conductivity type body contact adjacent to or in contact with the source.

According to yet one or more other embodiments of the present disclosure, the superjunction semiconductor device may further include a first conductivity type connection region connecting the pillars in a transition region (e.g., of the semiconductor device).

According to yet one or more other embodiments of the present disclosure, the superjunction semiconductor device may further include a first conductivity type well extending from the connection region to the ring region (e.g., of the semiconductor device).

According to yet one or more other embodiments of the present disclosure, a superjunction semiconductor device includes a substrate; a second conductivity type epitaxial layer on the substrate; first conductivity type pillars spaced apart from each other in the epitaxial layer; a first conductivity type body region on or in a surface of the epitaxial layer in a cell region (e.g., of the semiconductor device); a second conductivity type source in the body region; a gate oxide film on the epitaxial layer in the cell region; a gate electrode on the gate oxide film; and a second conductivity type impurity region between the substrate and the epitaxial layer in the cell region, wherein the impurity region may be a lightly doped region and may not be in a ring region (e.g., of the semiconductor device).

According to yet one or more other embodiments of the present disclosure, in the superjunction semiconductor device, the impurity region may be or comprise a thermally diffused ion implantation region on or in the substrate.

According to yet one or more other embodiments of the present disclosure, the superjunction semiconductor device may further include a field oxide film on the epitaxial layer in the ring region; and a gate runner on the field oxide film.

According to one or more embodiments of the present disclosure, a method for manufacturing a superjunction semiconductor device includes forming a second conductivity type impurity region on or in a substrate; forming an epitaxial layer on the substrate; forming first conductivity type pillars in the epitaxial layer; forming a gate oxide film on the epitaxial layer; forming a gate electrode on the gate oxide film; forming a first conductivity type body region in the epitaxial layer; and forming a second conductivity type source in the body region.

According to one or more other embodiments of the present disclosure, in the method for manufacturing a superjunction semiconductor device, forming the impurity region may include implanting second conductivity type impurities into a surface of the substrate in a cell region (e.g., of the semiconductor device); and performing a thermal diffusion process after implanting the second conductivity type impurities.

According to yet one or more other embodiments of the present disclosure, in the method for manufacturing a superjunction semiconductor device, forming the epitaxial layer may include forming an undoped epitaxial layer on the substrate after implanting the second conductivity type impurities; implanting additional second conductivity type impurities into the undoped epitaxial layer; and diffusing the additional second conductivity type impurities in the undoped epitaxial layer by the thermal diffusion process.

According to yet one or more other embodiments of the present disclosure, in the method for manufacturing a superjunction semiconductor device, the thermal diffusion process to form the impurity region may be performed after forming the undoped epitaxial layer and before implanting the additional second conductivity type impurities into the undoped epitaxial layer.

According to yet one or more other embodiments of the present disclosure, in the method for manufacturing a superjunction semiconductor device, the epitaxial layer may have the second conductivity type, and epitaxial layer may be formed by repeatedly (and, optionally, sequentially) forming the undoped epitaxial layer, implanting the additional second conductivity type impurities, and thermally diffusing the additional second conductivity impurities.

According to yet one or more other embodiments of the present disclosure, a method for manufacturing a superjunction semiconductor device includes forming a lightly doped second conductivity type impurity region on or in a substrate; forming a second conductivity type epitaxial layer on the substrate; forming first conductivity type pillars in the epitaxial layer; forming a gate oxide film on the epitaxial layer; forming a gate electrode on the gate oxide film; forming a first conductivity type body region in the epitaxial layer; and forming a second conductivity type source in the body region, wherein the impurity region may be formed in a cell region (e.g., of the semiconductor device).

According to yet one or more other embodiments of the present disclosure, the method for manufacturing a superjunction semiconductor device may further include forming a field oxide film on the epitaxial layer; and forming a gate runner on the field oxide film.

According to yet one or more other embodiments of the present disclosure, the method for manufacturing a superjunction semiconductor device may further include performing a thermal diffusion process after forming the impurity region.

According to yet one or more other embodiments of the present disclosure, the method for manufacturing a superjunction semiconductor device may further include forming a body contact in the body region; and forming a first conductivity type connection region in the epitaxial layer.

The present disclosure has the following effects by the above configurations.

The present disclosure can improve on-resistance characteristics of the semiconductor device while maintaining the ON-state breakdown voltage characteristics by forming a second conductivity type impurity region between a substrate or substrate layer and an epitaxial layer to increase an n-type impurity concentration, which results in a carrier increase.

In addition, the present disclosure can promote the convenience of manufacturing the semiconductor device and prevent degradation of the breakdown voltage characteristics by additionally performing only an ion implantation process on the substrate, without changing the thickness of the epitaxial layer and/or the pillar doping concentration.

Moreover, the present disclosure can further improve the on-resistance characteristics as a result of a relatively thick impurity region in the substrate, formed by a thermal diffusion process after the formation of a first undoped epitaxial layer.

Meanwhile, it should be added that even if effects not explicitly mentioned herein, the effects described in the present specification expected by the technical features of the present disclosure and their potential effects are treated as if they were explicitly described in the present specification.

### BRIEF DESCRIPTION OF DRAWINGS

FIG. 1 is a schematic cross-sectional view of a conventional superjunction semiconductor device;

FIG. 2 is a cross-sectional view of a superjunction semiconductor device according to one or more embodiments of the present disclosure;

FIGS. 3 to 12 are cross-sectional views for reference of a method for manufacturing a superjunction semiconductor device according to one or more embodiments of the present disclosure; and

FIG. 13 is a graph comparing donor concentration characteristics between a superjunction semiconductor device according to the present disclosure and the conventional device.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those of ordinary skill in the art.

As used herein, the singular form may include the plural form unless the context clearly dictates otherwise. Furthermore, as used herein, “comprise” and/or “comprising” refer to the specific existence of recited shapes, numbers, steps, actions, members, elements and/or groups thereof, and does not exclude the presence or addition of one or more other shapes, numbers, actions, members, elements and/or groups.

Hereinafter, it should be noted that when one component (or layer) is described as being on another component (or layer), one component may be directly on the other component, or one or more additional component(s) or layer(s) may be between the first two components. In addition, when one component is expressed as being directly on or above another component, no other component(s) are between the two components. Moreover, the terms “top”, “upper”, “lower”, “bottom” or “one (or a first) side” or “side” may refer to a relative positional relationship with regard to a component.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

Furthermore, the conductivity type or doped region of the components may be defined as “p-type” or “n-type” according to the main carrier characteristics, but this is only for convenience of description, and the technical spirit of the present disclosure is not limited to what is illustrated. For example, hereinafter, “p-type” or “n-type” may be replaced herein with the more general terms “first conductivity type” or “second conductivity type.” Herein, the first conductivity type may refer to p-type, and the second conductivity type may refer to n-type.

Furthermore, it should be understood that “high concentration” and “low concentration” with reference to the doping concentration of a given impurity region refers to the relative doping concentration of one component to other component(s).

A superjunction semiconductor device 1 according to one or more embodiments of the present disclosure may include a cell region C, which is an active region, and a ring region R, which is a termination region surrounding the cell region C. In addition, a transition region T may be between the cell region C and the ring region R.

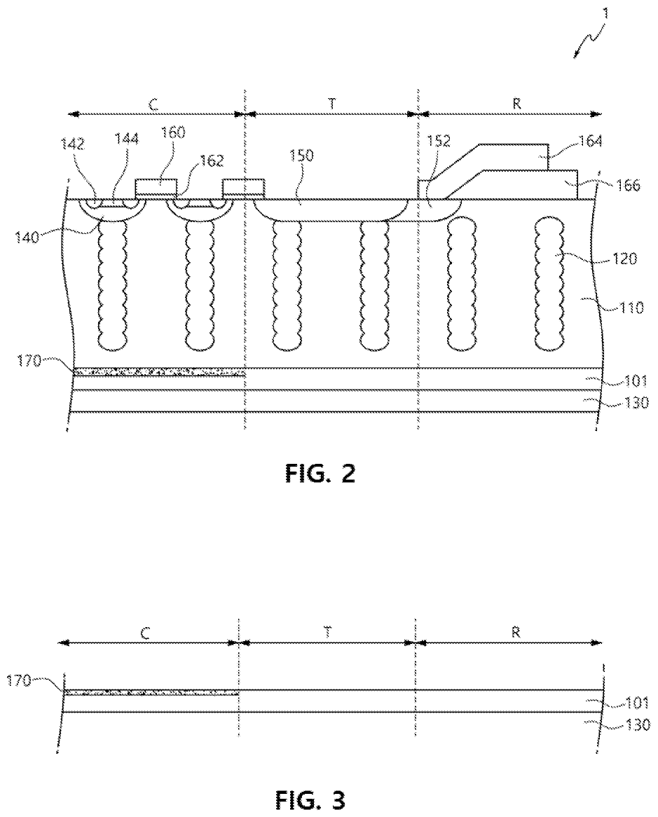

FIG. 2 is a cross-sectional view of a superjunction semiconductor device according to one or more embodiments of the present disclosure.

Hereinafter, a superjunction semiconductor device according to the present disclosure will be described in detail with reference to the accompanying drawings.

Referring to FIG. 2, the present disclosure relates to a superjunction semiconductor device 1 and a method for manufacturing the same and, more particularly, to a superjunction semiconductor device 1 and a method for manufacturing the same seeking to improve on-resistance characteristics (Ron) without degrading breakdown voltage characteristics of the device by forming a second conductivity type impurity region on/in (e.g., on or in a surface or side of) a substrate in a cell region C to increase a second conductivity type impurity concentration in the device.

First, a substrate (or substrate layer) 101 may be provided for the superjunction semiconductor device. The substrate 101 may include a silicon substrate, a germanium substrate, and may include a bulk wafer (e.g., a monolithic and/or single crystal silicon wafer). The substrate 101 may have a first conductivity type. The epitaxial layer 110 is in the entire C, T, and R regions on the substrate 101. The epitaxial layer 110 is a second conductivity type impurity doped region (e.g., it has the second conductivity type).

In addition, in the second conductivity type epitaxial layer 110, a plurality of pillars 120 may be spaced apart from each other in the lateral direction. These pillars 120 are first conductivity type impurity doped regions that alternate with regions of the (unmodified) epitaxial layer 110 along the lateral direction. The pillars 120 may have curved surfaces in contact with the epitaxial layer 110 (e.g., the interface between the pillars 120 and the epitaxial layer 110 may comprise complementary curved surfaces). Alternatively, the pillars 120 may have substantially flat lateral surfaces, and there is no limitation thereto.

A drain electrode 130 is under the substrate 101 (e.g., on the opposite side or surface of the substrate 101 from the epitaxial layer 110). The drain electrode 130 may be in the entire C, T, and R regions. In the cell region C, a body region 140 is on each pillar 120 in the epitaxial layer 110. The body region 140 may have a predetermined depth and may extend laterally. The body region 140 is a first conductivity type impurity doped region, and may be electrically or ohmically connected to a respective pillar 120 (e.g. at an uppermost end or side of the pillar 120). Accordingly, the body region 140 may be matched one-to-one with the pillars 120 in the cell region C. One or more sources 142 may be in the body region 140. The source(s) 142 comprise a second conductivity type impurity, and may have a high concentration of the impurity. For example, it is preferable that two sources 142 are in each of the body regions 140 so that current flows through channels on opposite sides of the individual pillars 120, but is not limited thereto.

In addition, in the body region 140, a body contact 144 may be adjacent to or in contact with the source(s) 142. The body contact 144 may comprise a heavily doped first conductivity type region.

In the transition region T, a connection region 150 may extend laterally and have a predetermined depth in the epitaxial layer 110. The connection region 150 connects the pillars 120 in the transition region T to each other (e.g., along their uppermost surfaces). Accordingly, the pillars 120 in the transition region T may share the connection region 150. The connection region 150 may be a heavily doped first conductivity type region having substantially the same doping concentration as that of the body region 140. A first conductivity type well 152 extending from the connection region 150 toward the ring region R is in the epitaxial layer 110 in the transition region T and optionally in the ring region R. The well 152 may have a lower doping concentration than the connection region 150, and may provide a current movement path during reverse recovery.

A gate electrode 160 is on or over the surface of the epitaxial layer 110 in the cell region C. A channel region is turned on and off by the voltage applied to the gate electrode 160. The gate electrode 160 may comprise conductive polysilicon, metal, conductive metal nitride, or a combination thereof. A gate oxide film 162 may be between the gate electrode 160 and the surface of the epitaxial layer 110. The gate oxide film 162 may comprise a silicon oxide film, a high-k film, or a combination thereof.

In addition, a gate runner 164 may be on and/or over the surface of the epitaxial layer 110 in the ring region R. Like the gate electrode 160, the gate runner 164 may also comprise conductive polysilicon, metal, conductive metal nitride, or a combination thereof. A field oxide film 166 may be between the gate runner 164 and the surface of the epitaxial layer 110.

Hereinafter, the structure of the conventional superjunction semiconductor device 9 and problems thereof, and the structure of the semiconductor device 1 according to the present disclosure for solving these problems will be described in detail.

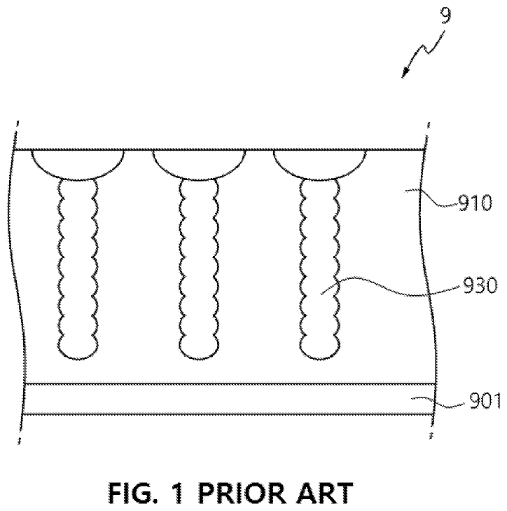

Referring to FIG. 1, in the conventional superjunction semiconductor device 9, a second conductivity type epitaxial layer 910 is on a first conductivity type substrate 901. A plurality of first conductivity type pillar regions 930 are in the epitaxial layer 910, spaced apart from each other in a lateral direction. In such a device 9, it is difficult to improve device characteristics by implementing a high breakdown voltage value with a low on-resistance value because the on-resistance value and the breakdown voltage value have a trade-off relationship. That is, when the surface resistance value decreases for a low on-resistance value, during the ON operation of the device, the breakdown voltage value decreases as a high electric field is formed in or near the surface. Conversely, when the doping concentration in or adjacent to a p-n junction is optimized to improve the ON-state breakdown voltage, the on-resistance value increases.

In order to solve this problem, referring to FIG. 2, the superjunction semiconductor device 1 includes a second conductivity type impurity region 170 not on the side of or adjacent to the junction between the pillar 120 and the epitaxial layer 110, but on or in the substrate 101, below and/or in contact with the epitaxial layer 110. That is, the second conductivity type impurity region 170 of a predetermined depth is formed by ion implantation of the second conductivity type impurities into the substrate 101 (e.g., the uppermost surface thereof). The impurity region 170 may be or comprise a low-concentration second conductivity type impurity region, having a relatively lower dopant concentration than that of the epitaxial layer 110. As such, by increasing the overall concentration of the second conductivity type impurity in the cell region C, the on-resistance characteristics may be improved without changing the breakdown voltage characteristics of the device 1. In addition, there may be manufacturing advantages since the second conductivity type impurity region 170 may be implemented by a single additional ion implantation of second conductivity type impurities on or in the substrate 101, without changing the thickness of the epitaxial layer 110 or the pillar 120 doping concentration.

In a typical superjunction semiconductor device, since the current path in the ON-state is in the cell region C, the impurity region 170 is preferably in the cell region C, but is not limited thereto.

FIGS. 3 to 12 are cross-sectional views for reference of a method for manufacturing a superjunction semiconductor device according to one or more embodiments of the present disclosure.

Hereinafter, a method for manufacturing a superjunction semiconductor device according to the present disclosure will be described in detail with reference to the accompanying drawings.

First, referring to FIG. 3, the impurity region 170 is formed on or in the surface of the substrate 101. To be specific, the impurity region 170 may be formed by forming a mask pattern (not shown) on the substrate 101, the mask pattern having an opening exposing the cell region C of the substrate 101, and then performing an ion implantation process. The ion implantation process may comprise implanting a low-concentration of second conductivity type impurities into the cell region C. Accordingly, a second conductivity type impurity region 170 is formed on or in the surface of the substrate 101 in the cell region C. Alternatively, the impurity region 170 may also be formed in part or all of the transition region T (e.g., adjacent to the cell region C).

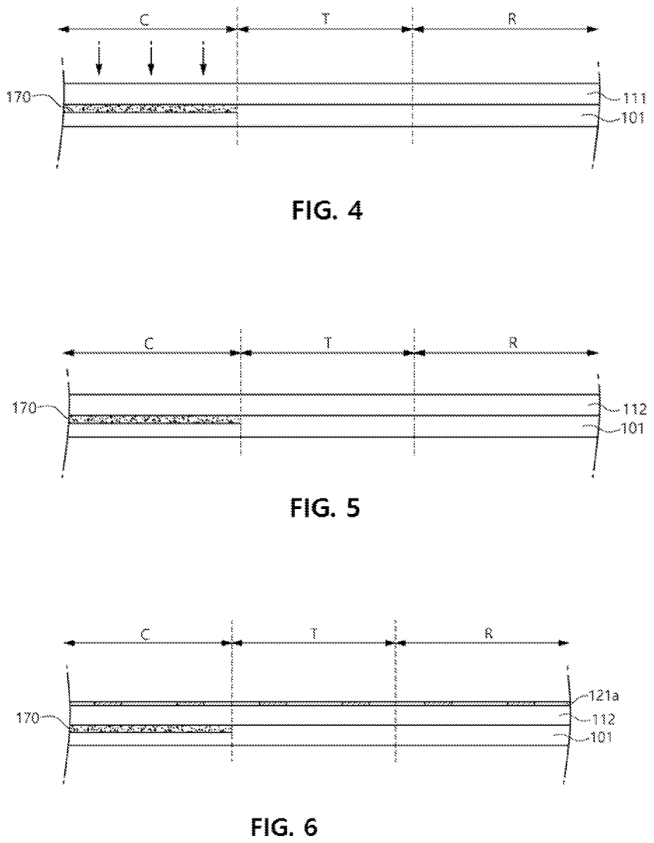

Thereafter, referring to FIG. 4, in order to form the second conductivity type epitaxial layer 110 on the substrate 101, a first undoped epitaxial layer 111 is formed (e.g., by epitaxial growth of silicon from a silane [e.g., SiH₄, SiHCl₃, etc.] gas). Thereafter, a thermal diffusion process is performed to diffuse and/or activate the dopants in the impurity region 170. Through such a thermal diffusion process, the impurity region 170 may be diffused to a relatively deep portion of the substrate 101. Therefore, compared to not performing the thermal diffusion process, an additional on-resistance characteristic improvement effect may occur, which will be described later.

Thereafter, a second conductivity type impurity is implanted into the first undoped epitaxial layer 111. For example, the second conductivity type impurity may be implanted into the first undoped epitaxial layer 111, in at least the cell region C (but optionally the entire epitaxial layer 111), in a concentration or dose greater than that of the impurity region 170. The second conductivity type impurity in the first undoped epitaxial layer 111 may be diffused and/or activated using a thermal diffusion process. Accordingly, referring to FIG. 5, a first doped epitaxial layer 112 may be formed.

Thereafter, referring to FIG. 6, a first conductivity type implant layer 121a may be formed by implanting a first conductivity type impurity in a predetermined portion of the first doped epitaxial layer 112. The first conductivity type implant layer 121 may be formed, for example, by ion implantation after forming a mask pattern (not shown) on the substrate 101, the mask pattern having an opening exposing the areas of the first doped epitaxial layer 112 in which the pillar regions 120 are to be formed. The ion implantation process may comprise implanting a high concentration of second conductivity type impurities into the first doped epitaxial layer 112.

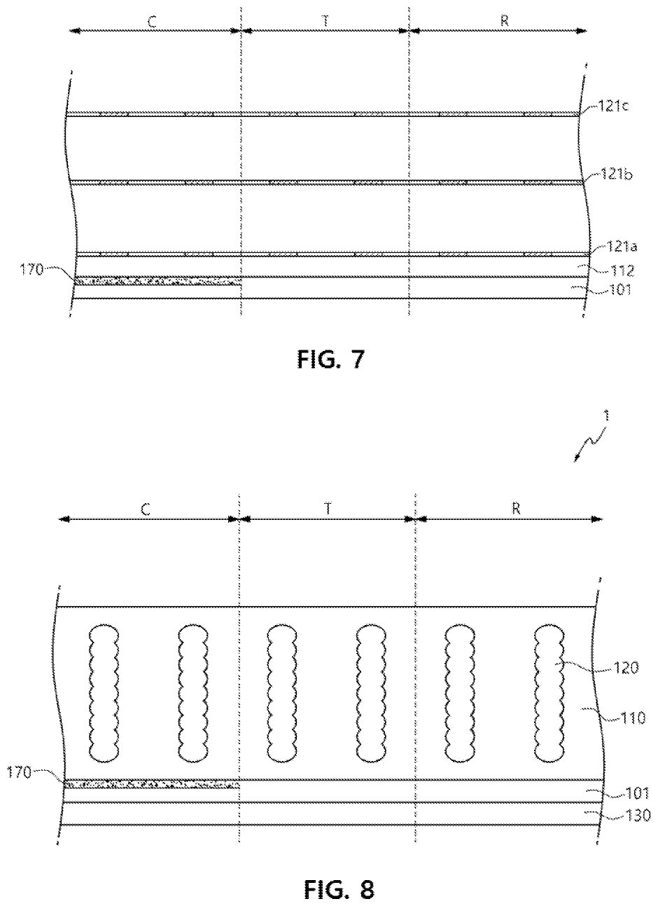

Thereafter, referring to FIG. 7, the process of forming the first undoped epitaxial layer 111, the first doped epitaxial layer 112, and the first conductive implant layer 121 is repeatedly performed on the first doped epitaxial layer 112. That is, a second undoped epitaxial layer growth, a second ion implantation into the second undoped epitaxial layer, a second thermal diffusion, and a second implantation of first conductivity type impurities (to form implant layer 121b) are conducted on the first doped implant layer 121a. This process is repeated a predetermined number of times.

Thereafter, referring to FIG. 8, an additional thermal diffusion process is performed so that the first conductivity type implant layers 121a-c are diffused in each of the first doped epitaxial layer 112 and second doped epitaxial layers (not numbered in FIG. 7). Accordingly, the pillars 120 may be formed after the additional thermal diffusion process.

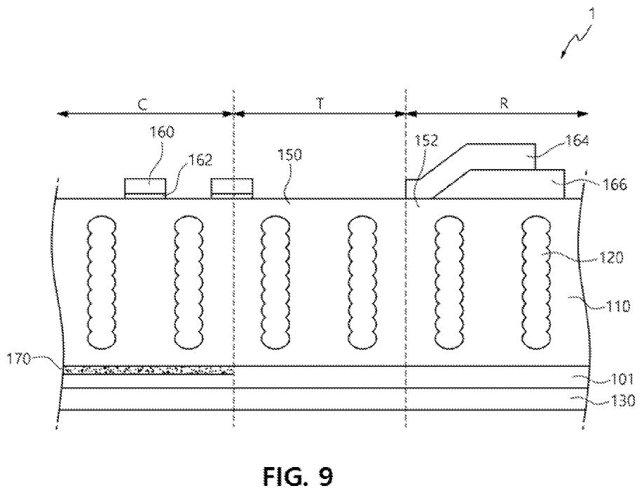

Thereafter, referring to FIG. 9, the field oxide film 166 is formed on and/or in the epitaxial layer 110. For example, an insulating film (not shown) may be deposited on the epitaxial layer 110, and the insulating film is etched using a mask pattern (not shown) in the ring region R covering the insulating film where the field oxide film 166 is to remain. Alternatively, the field oxide film 166 may be formed by a fully recessed, partially recessed, or unrecessed LOCOS (local oxidation of silicon) process, or a shallow trench isolation (STI) process.

Then, another insulating film (not shown) for forming the gate oxide film 162 is formed on the epitaxial layer 110 in the cell region C. The gate oxide film 162 may be formed by deposition of a thin insulating film or by wet or dry oxidation of exposed areas of the epitaxial layer 110.

In addition, the gate electrode 160 and the gate runner 164 are formed. In one example, the gate electrode 160, the gate runner 164, and the gate oxide film 162 may be formed in the same processing sequence by forming the insulating film for the gate oxide film 162 on the epitaxial layer 110, depositing an electrically conductive film for the gate electrode 160 and the gate runner 164 on the insulating film, forming a mask pattern (not shown) on the electrically conductive film, and etching the insulating film and the electrically conductive film sequentially in the same etching apparatus (e.g., without intermediate cleaning). The electrically conductive film may comprise, for example, a doped polysilicon layer, and the gate electrode 160 may have an elongated oval or substantially rectangular (e.g., stripe) shape in a layout (top-down) view. The gate electrodes 160 and the gate oxide films 162 may be between adjacent pillars 120 in the cell region C, although an outermost gate electrode 160 and gate oxide film 162 may define at least in part an interface between the cell region C and the transition region T.

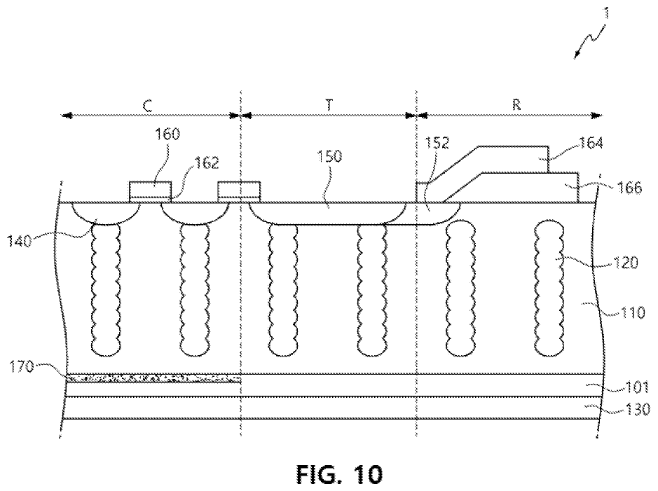

Thereafter, referring to FIG. 10, the body region 140, the connection region 150, and the well 152 are formed. The well 152 may be formed by implanting first conductivity type impurities at a low concentration into the epitaxial layer 110 using the gate electrode 160 and the gate runner 164 extending toward the transition region T as a mask pattern, but there is no limitation thereto. For example, the well region 152 may be formed by implanting the first conductivity type impurities into the epitaxial layer 110 using the field oxide film 166 (and a mask pattern [not shown] covering the cell region C) as a mask. In addition, the body region 140 and the connection region 150 may be formed in the cell region C and the transition region T by implanting first conductivity type impurities using the gate electrodes 160 and the gate runner 164 as a mask.

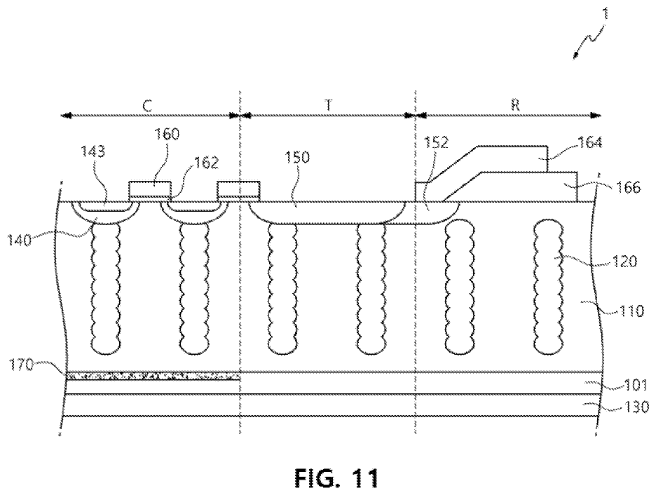

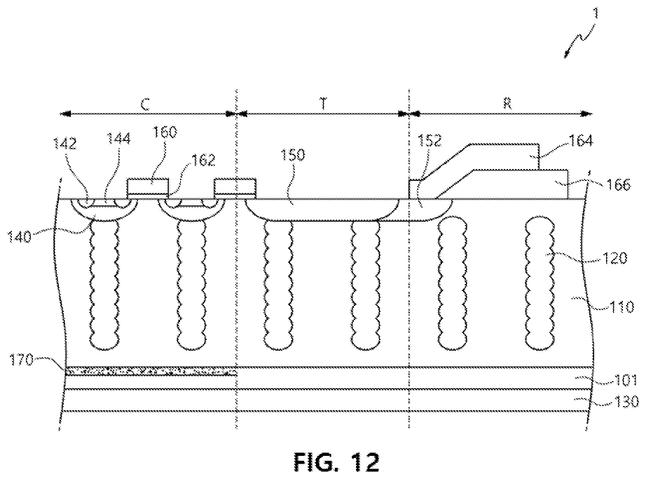

Then, a source 142 is formed in the body region 140 in the cell region C. For example, referring to FIG. 11, second conductivity type impurities are implanted into the body region 140 using a mask pattern (not shown) and optionally the gate electrodes 160 as a mask to form an implant region 143. Then, referring to FIG. 12, a body contact 144 may be formed by implanting first conductivity type impurities into the body region 140. More specifically, the first conductivity type impurities are implanted into the implant region 143 in the body region 140 to a depth making ohmic or electric contact with the body region 140 under the implant region 143, followed by thermal diffusion and/or activation, to form body contacts 144 and sources 142.

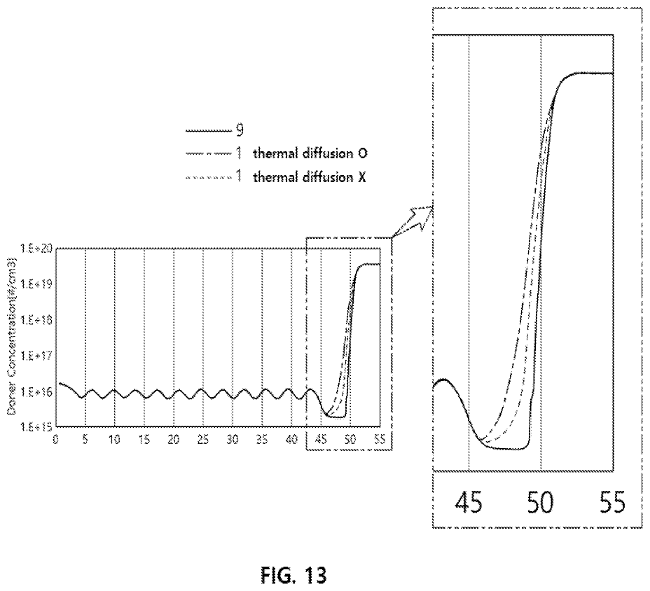

FIG. 13 is a graph comparing donor concentration characteristics between a superjunction semiconductor device according to the present disclosure and a conventional device (e.g., such as the device 9 in FIG. 1).

Referring to FIG. 13, advantages of the superjunction semiconductor device 1 according to the present disclosure will be described. First, in the conventional device 9, the donor concentration rapidly decreases at the boundary between the substrate 901 and the epitaxial layer 910 (e.g., at or around a depth of about 45 μm), going from the second conductivity type epitaxial layer 910 to the first conductivity type substrate 901. In contrast to this, in the device 1 according to the present disclosure in which the thermal diffusion process is not performed after the formation of the first undoped epitaxial layer 111 (i.e., thermal diffusion X), the donor concentration decreases relatively gently at the same location, and an additional effect is obtained when the thermal diffusion process is performed (i.e., thermal diffusion O). Therefore, the amount of current passing through the channel may increase compared to the conventional device 9, which means that the on-resistance characteristics may improve relative to the conventional device 9.

The above detailed description is illustrative of the present disclosure. In addition, the above description shows and describes various embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiments describe various ways to implement the technical ideas of the present disclosure, and various changes for specific application fields and uses of the present disclosure are possible. Accordingly, the detailed description of the present disclosure is not intended to limit the present disclosure to the disclosed embodiments.

1. A superjunction semiconductor device, comprising:
a substrate;
a second conductivity type epitaxial layer on the substrate;
a plurality of first conductivity type pillars laterally spaced apart from each other in the epitaxial layer;
a first conductivity type body region connected to one of the pillars in the epitaxial layer in a cell region;
a second conductivity type source in the body region;
a gate oxide film on the epitaxial layer;
a gate electrode on the gate oxide film;
a drain electrode on the substrate; and
a second conductivity type impurity region on or in the substrate.

2. The superjunction semiconductor device of claim 1, wherein the impurity region comprises a lightly doped region.

3. The superjunction semiconductor device of claim 1, wherein the impurity region is in the cell region.

4. The superjunction semiconductor device of claim 1, further comprising:
a first conductivity type body contact adjacent to or in contact with the source in the body region.

5. The superjunction semiconductor device of claim 1, further comprising:
a first conductivity type connection region connecting the pillars in a transition region.

6. The superjunction semiconductor device of claim 5, further comprising:
a first conductivity type well extending from the connection region to a ring region.

7. A superjunction semiconductor device, comprising:
a substrate;
a second conductivity type epitaxial layer on the substrate;
first conductivity type pillars that are spaced apart from each other in the epitaxial layer;
a first conductivity type body region in the epitaxial layer in a cell region;
a second conductivity type source in the body region;
a gate oxide film on the epitaxial layer in the cell region;
a gate electrode on the gate oxide film; and
a lightly-doped second conductivity type impurity region between the substrate and the epitaxial layer in the cell region,
wherein the impurity region is not in a ring region.

8. The superjunction semiconductor device of claim 7, wherein the impurity region comprises a thermally diffused ion implantation region on or in the substrate.

9. The superjunction semiconductor device of claim 8, further comprising:
a field oxide film on the epitaxial layer in the ring region; and
a gate runner on the field oxide film.

10. A method for manufacturing a superjunction semiconductor device, the method comprising:
forming a second conductivity type impurity region on or in a substrate;
forming an epitaxial layer on the substrate;
forming first conductivity type pillars in the epitaxial layer;
forming a gate oxide film on the epitaxial layer;
forming a gate electrode on the gate oxide film;
forming a first conductivity type body region in the epitaxial layer; and
forming a second conductivity type source in the body region.

11. The method for manufacturing a superjunction semiconductor device of claim 10, wherein forming the impurity region includes:
implanting second conductivity type impurities into a surface of the substrate in a cell region; and
performing a thermal diffusion process after implanting the second conductivity type impurities.

12. The method for manufacturing a superjunction semiconductor device of claim 11, wherein forming the epitaxial layer includes:
forming an undoped epitaxial layer on the substrate after implanting the second conductivity type impurities;
implanting additional second conductivity type impurities into the undoped epitaxial layer; and
diffusing the additional second conductivity type impurities in the undoped epitaxial layer by the thermal diffusion process.

13. The method for manufacturing a superjunction semiconductor device of claim 12, wherein the thermal diffusion process is performed after forming the undoped epitaxial layer and before implanting the additional second conductivity type impurities into the undoped epitaxial layer.

14. The method for manufacturing a superjunction semiconductor device of claim 12, wherein the second conductivity type epitaxial layer is formed by repeatedly forming the undoped epitaxial layer, implanting the additional second conductivity type impurities, and diffusing the additional second conductivity type impurities.

15. A method for manufacturing a superjunction semiconductor device, the method comprising:
forming a lightly doped second conductivity type impurity region in a cell region of a substrate;
forming a second conductivity type epitaxial layer on the substrate;
forming first conductivity type pillars in the epitaxial layer;
forming a gate oxide film on the epitaxial layer;
forming a gate electrode on the gate oxide film;
forming a first conductivity type body region in the epitaxial layer; and
forming a second conductivity type source in the body region.

16. The method for manufacturing a superjunction semiconductor device of claim 15, further comprising:
forming a field oxide film on the epitaxial layer; and
forming a gate runner on the field oxide film.

17. The method for manufacturing a superjunction semiconductor device of claim 15, further comprising:
performing a thermal diffusion process after forming the impurity region.

18. The method for manufacturing a superjunction semiconductor device of claim 15, further comprising:
forming a body contact in the body region; and
forming a first conductivity type connection region in the epitaxial layer.
